(19) United States
(12) Patent Application Publication
(10) Pub. No.: US 2023/0314128 A1
(43) Pub. Date: Oct. 5, 2023

(54) Processing System and Charged Particle Beam Apparatus

(71) Applicant: Hitachi High-Tech Corporation, Tokyo (JP)

(72) Inventors: Masaya GOTO, Tokyo (JP); Kei SAKAI, Tokyo (JP); Satoru YAMAGUCHI, Tokyo (JP); Junichi KAKUTA, Tokyo (JP)

(21) Appl. No.: 18/127,858

(22) Filed: Mar. 29, 2023

(30) Foreign Application Priority Data
Mar. 31, 2022 (JP) 2022-060349

(51) Int. Cl. H01J 37/28; G01B 21/30

(52) U.S. Cl. CPC G01B 21/30; H01J 37/28; H01J 2237/0437; H01J 2237/24592; H01J 2237/2817

(57) ABSTRACT

A processing system and a charged particle beam apparatus for the purpose of determining the degree of growth or the presence or absence of a defect in an epitaxial layer grown in a groove or a hole such as between inner spacers from an image of the groove or the hole are proposed. In a processing system including a computer system, the computer system calculates a distance and a brightness value related to a layer between a plurality of structures from a signal profile in accordance with one direction on a two-dimensional plane related to the layer, which is obtained by irradiating the layer with an electron beam, and determines or outputs a state of the layer based on the distance and the brightness value.

### TECHNICAL FIELD

The present invention relates to a processing system and a charged particle beam apparatus.

### BACKGROUND ART

Recently, a semiconductor device has been miniaturized, and accordingly, a process window for epitaxial growth has become narrower. Along with this, an inner spacer is used to prevent epitaxial layers from being coupled together when the epitaxial layers are closely disposed. On the other hand, a charged particle beam apparatus such as a scanning electron microscope has been used to manage a manufacturing process for the semiconductor device. The scanning electron microscope (SEM) is an apparatus that acquire pattern images and signal waveforms by scanning fine patterns with focused electron beams and is an apparatus capable of scanning and inspecting the fine patterns. However, since electrons emitted from the epitaxial layer collide with a side wall such as the inner spacer or a dummy gate before the electrons are emitted to the surface of a sample, the efficiency of detection is low, and consequently, it is difficult to measure the epitaxial layer with high accuracy.

PTL 1 discloses a scanning electron microscope that improves pattern images for inspecting a defect in a lower layer. More specifically, a method of utilizing a difference in penetration depth of electrons into a sample due to acceleration voltages to acquire images using two types of acceleration voltages and taking a difference therebetween to emphasize an underlying pattern is disclosed.

### CITATION LIST

### Patent Literature

PTL 1: US2010/0136717A

### SUMMARY OF INVENTION

### Technical Problem

When an acceleration voltage is changed, not only an epitaxial layer in a groove portion between inner spacers, but also a generated SEM image itself varies greatly due to a difference in the efficiency of detection. In addition, even when electrons reach the epitaxial layer portion, it is obvious that secondary electrons collide with a side walls, thereby lowering the efficiency of detection. As disclosed in US2010/0136717 (PTL 1), even when imaging is performed again by changing the acceleration voltage, only the epitaxial layer in the groove between the inner spacers cannot be emphasized, making it difficult to perform highly accurate measurement.

On the other hand, in recent semiconductor devices, in order to increase an on-current of a transistor, mobility is improved using a lattice distortion by epitaxially growing a material with a different lattice constant, such as SiGe relative to Si. When the epitaxial layer is excessively thin, resistance between a source and a drain is large, and a sufficient on-current of the transistor cannot be obtained. When the epitaxial layer is excessively thick, a contact with a spacer portion or a high-K film increases, thereby increasing capacitance and lowering response performance of the transistor. For this reason, it is necessary to appropriately manage the growth of the epitaxial layer. In addition, a result of epitaxial growth varies depending on a difference between an N-type and a P-type, a wafer surface, and a distance between inner spacers, and thus it is necessary to perform observation and measurement.

Although it is desirable to use an electron microscope capable of measuring and inspecting fine patterns for measurement, the amount of secondary electrons detected in the epitaxial layer is smaller than in other regions such as the inner spacer, and thus it is extremely difficult to observe the epitaxial layer. Furthermore, in recent semiconductor process management, there is a high demand for efficiency in measurement and inspection, and automation is required.

The invention has been made to solve such problems, and proposes the following processing system and charged particle beam apparatus for the purpose of determining the degree of growth or the presence or absence of a defect in an epitaxial layer grown in a groove or a hole such as between inner spacers from an image of the groove or the hole.

### Solution to Problem

An example of a processing system according to the invention is a processing system including a computer system, in which the computer system calculates a distance and a brightness value related to a layer between a plurality of structures from a signal profile in accordance with one direction on a two-dimensional plane related to the layer, which is obtained by irradiating the layer with an electron beam, and determines or outputs a state of the layer based on the distance and the brightness value.

An example of a charged particle beam apparatus according to the invention includes the above-described processing system.

### Advantageous Effects of Invention

According to the above configuration, it is possible to measure the degree of growth or determine the presence or absence of a defect in an epitaxial layer grown in a groove or a hole between inner spacers from an image of the groove or the hole.

### BRIEF DESCRIPTION OF DRAWINGS

FIG. 1 is an overall schematic diagram illustrating a scanning electron microscope according to Example 1 of the present disclosure.

FIG. 2 illustrates a flow of recipe registration in Example 1.

FIGS. 3A to 3F illustrate a relationship between a cross-sectional view, a top view, and a profile after epitaxial growth in Example 1.

FIG. 4 illustrates an example of a GUI for determining a threshold value in Example 1.

FIG. 5 illustrates a flow of recipe execution in Example 1.

FIGS. 6A to 6C illustrate an example in which a width of an epitaxial portion is measured in a case where there is a brightness equal to or less than the threshold value in Example 1.

FIGS. 7A to 7C illustrate an example in which a distance between inner spacers is measured in a case where there is no brightness equal to or less than the threshold value in Example 1.

FIG. 8 illustrates an example of a GUI for determining a threshold value in Example 2 of the present disclosure.

FIG. 9 illustrates an example of a GUI for determining a threshold value in Example 3 of the present disclosure.

FIG. 10 illustrates a flow of recipe execution in Example 3.

FIG. 11 illustrates an example in a case where there is no inner spacer or a signal is weak in Example 4.

### DESCRIPTION OF EMBODIMENTS

Examples of the present disclosure will be described below with reference to the accompanying drawings.

### Example 1

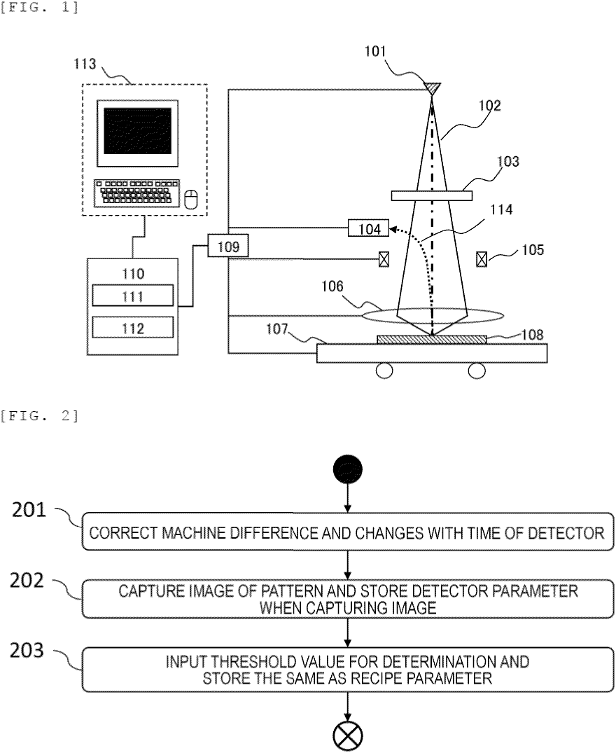

FIG. 1 is an overall schematic diagram illustrating a scanning electron microscope (charged particle beam apparatus) according to Example 1 of the present disclosure. An apparatus configuration in FIG. 1 will be described. A deformed illumination diaphragm 103, a detector 104, a scanning deflection deflector 105, and an objective lens 106 are disposed in a downstream direction in which an electron beam 102 is extracted from an electron source 101. Further, an electron optical system is also provided with an aligner for adjusting the central axis (optical axis) of a primary beam, an aberration corrector, and the like (not illustrated).

Although an example in which the objective lens 106 in the present example is an electromagnetic lens that controls a focus by an exciting current is described, the objective lens 106 may be an electrostatic lens or a combination of the electromagnetic lens and the electrostatic lens. A stage 107 is configured to move with a wafer, that is, a sample 108 placed thereon.

A controller 109 is connected to each unit of the electron source 101, the detector 104, the scanning deflection deflector 105, the objective lens 106, and the stage 107, and furthermore, a system control unit 110 is connected to the controller 109.

The system control unit 110 includes a computer system and functions as a processing system according to the present example. The operation of the system control unit 110 is implemented by the computer system. In the computer system of the system control unit 110, a storage device 111 and a computation unit 112 are disposed functionally, and an input/output unit 113 equipped with an image display device is connected.

Although not illustrated in the drawing, components other than a control system and a circuit system of the system control unit 110 are disposed in a vacuum container, and are operated by being evacuated. In addition, a wafer transfer system for disposing a wafer on a stage from outside a vacuum is provided.

More specifically, the system control unit 110 is configured to include a central processing unit, which is the computation unit 112, and a storage unit, which is the storage device 111. The central processing unit is used as the computation unit 112 described above and executes a program or the like stored in the storage apparatus 111, whereby it is possible to perform image processing related to defect inspection or dimension measurement, or control of the controller 109 or the like.

In this specification, the system control unit 110, the input/output unit 113, the controller 109, and the like may be collectively referred to as a control unit. Further, in the input/output unit 113, an input means such as a keyboard or a mouse and a display means such as a liquid crystal display device may be configured separately as an input unit and an output unit, or may be configured as an integrated input/output means using a touch panel or the like.

Image observation performed using an apparatus will be described. The focus of the electron beam 102 emitted from the electron source 101 is controlled by the objective lens 106, and the electron beam 102 is converged on the sample 108 so that a beam diameter is minimized. The scanning deflection deflector 105 is controlled by the controller 109 so that a defined region of the sample 108 is scanned with the electron beam 102.

When the electron beam 102 reaches a surface of the sample 108, the electron beam 102 interacts with a material near the surface. Electrons such as backscattered electrons, secondary electrons, or Auger electrons, which are derived from the interaction, are generated from the sample and become a signal to be acquired. In the present example, a case where the signal is secondary electrons will be described.

A secondary electron 114 generated from a position where the electron beam 102 reaches the sample 108 is detected by the detector 104. A SEM image is formed by performing signal processing of the secondary electron 114 detected from the detector 104 in synchronization with a scanning signal transmitted to the scanning deflection deflector 105 from the controller 109, and the sample 108 is observed. Although the detector 104 is disposed upstream of the objective lens 106 and the scanning deflection deflector 105 in the present example, the order of arrangement may be changed.

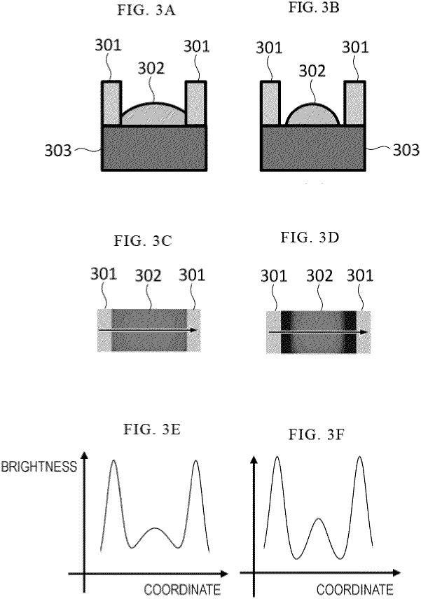

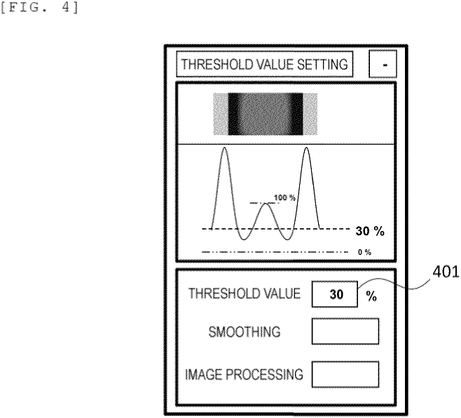

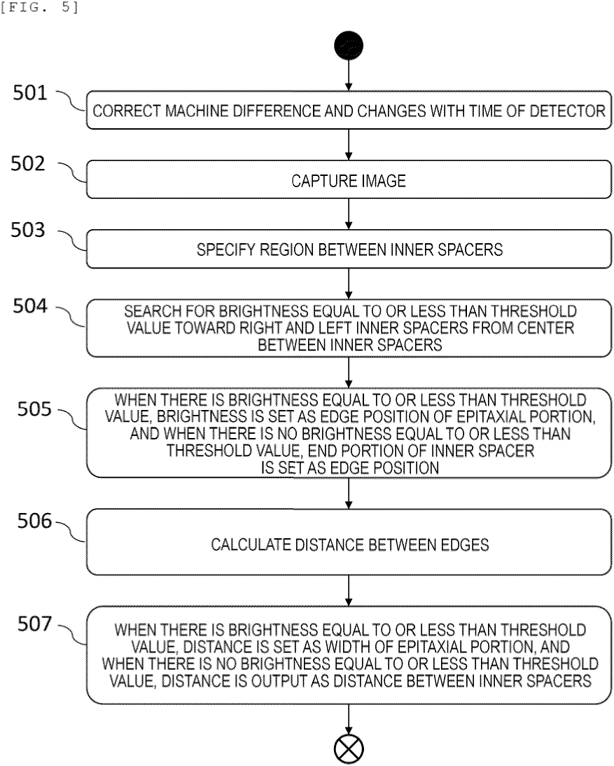

In the present example, recipe registration and execution using a brightness profile will be described. FIG. 2 illustrates a flow of recipe registration, FIG. 3 illustrates a relationship between a cross-sectional view, a top view, and a profile after epitaxial growth, and FIG. 4 illustrates an example of a graphical user interface (GUI) for determining a threshold value.

The execution of the processing in FIG. 2 is controlled by the system control unit 110. In FIG. 2, first, a machine difference and changes with time of the detector are corrected in order to compare brightness values (201). For example, a characteristic curve of a brightness amplification factor according to a voltage applied to the detector may be acquired and corrected, or may be corrected from an offset of the brightness of the same pattern.

Next, an image of a pattern of the sample 108 to be measured is captured, and a detector parameter when the image is captured is stored (202). An offset corresponding to brightness correction may be added to the captured image.

In a region where epitaxial growth is insufficient, the brightness is lower than in a region other than an epitaxial portion (such as an inner spacer) and a sufficiently grown epitaxial portion. This will be described using FIG. 3.

FIG. 3A is a cross-sectional view when epitaxial growth is sufficient, and FIG. 3B is a cross-sectional view when epitaxial growth is insufficient. Although an epitaxial portion 302 (epitaxial growth layer) is grown between two inner spacers 301 on a substrate 303, the degree of growth of the epitaxial portion 302 in FIG. 3B is lower than in FIG. 3A.

FIG. 3C is a top view when epitaxial growth is sufficient and corresponds to FIG. 3A. FIG. 3D is a top view when epitaxial growth is insufficient and corresponds to FIG. 3B. An arrow represents a scanning direction of a charged particle beam, that is, a time-axis direction of a signal profile. This direction is one direction on a two-dimensional plane related to the epitaxial growth layer, and the signal profile is generated in accordance with this direction. The brightnesses in regions at both ends of the epitaxial portion 302 in FIG. 3D are lower than in FIG. 3C.

FIG. 3E is a profile of an image (signal profile) when epitaxial growth is sufficient, and FIG. 3F is a profile of an image (signal profile) when epitaxial growth is insufficient.

Note that the inner spacer (structure) can be, for example, a semiconductor fin-type gate layer. In this manner, appropriate processing can be performed in a semiconductor device having a specific structure.

In FIG. 2, after step 202, the threshold value (for example, a unit of %) for determining the degree of growth of the epitaxial portion is input and stored as a recipe parameter (203) .

For example, in a case where the brightness of a certain region is 30% or less of the maximum brightness of the epitaxial portion in the epitaxial portion or between two inner spacers, it is defined that epitaxial growth is insufficient in the region. The value “30%” is recorded as recipe information. Alternatively, “3,000”, which is the brightness value itself, may be used as the threshold value.

For example, in the GUI illustrated in FIG. 4, a user judges and determines the threshold value, and inputs the threshold value in, for example, a threshold value input column 401. In this example, the threshold value is 30%. The system control unit 110 receives and stores the threshold value.

FIG. 5 illustrates a flow of recipe execution. The execution of the processing in FIG. 5 is controlled by the system control unit 110. First, similarly to the recipe registration, the machine difference and the changes with time of the detector are corrected in order to compare the brightness values (501).

Thereafter, an image is captured (502). The offset corresponding to the brightness correction may be added to the captured image.

Next, a region between inner spacers is specified (503). In this specification, the “between inner spacers” means between two inner spacers. As a specific example, a plurality of first positions related to regions of a plurality of structures (two inner spacers in the present example) are specified based on the signal profile, and regions between the first positions are specified.

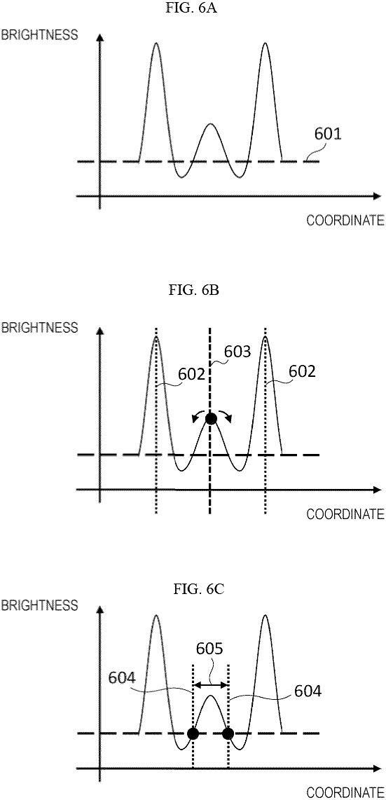

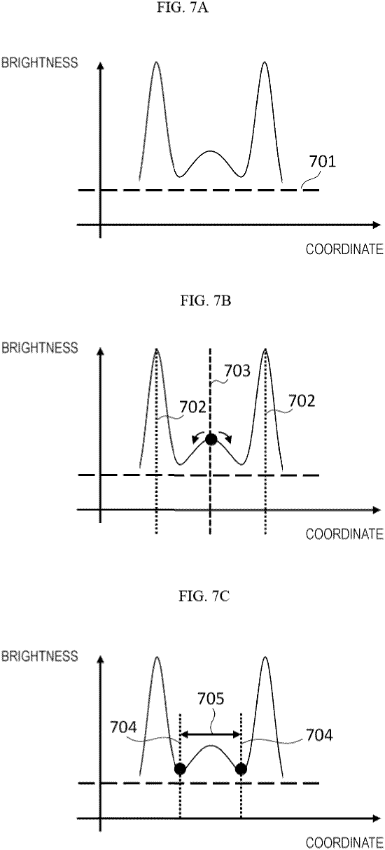

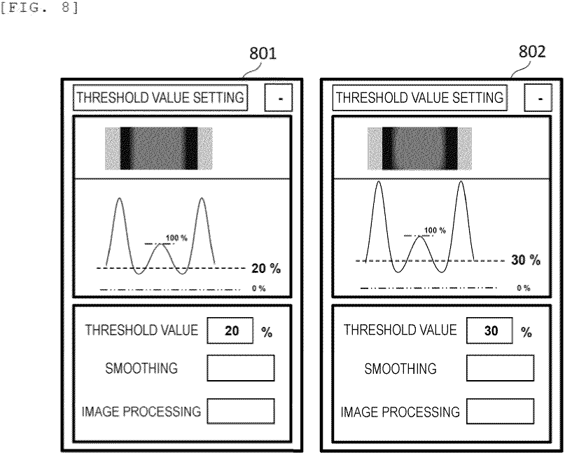

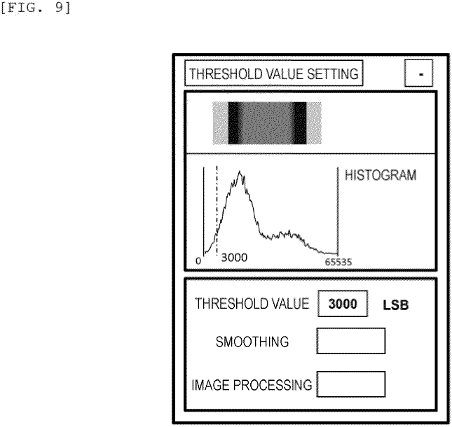

An example of this processing will be described using FIGS. 6A to 7C. FIGS. 6A to 6C are an example of the profile of the image when epitaxial growth is insufficient, and FIGS. 7A to 7C are an example of a profile of an image when epitaxial growth is insufficient.

FIGS. 6A and 7B illustrate respective signal profiles, where threshold values 601 and 701 represent threshold values registered in a recipe (for example, those input in the GUI of FIG. 4). FIGS. 6B and 7B illustrate examples of an inner spacer position 602 (first position) and an inner spacer position 702 (first position).

The inner spacer position is specified, for example, as a peak position of the signal profile, but other specification methods may be used. More specifically, the inner spacer position may be detected by binarization, a zero cross of a primary differential of a profile, a peak value of a secondary differential of a profile, or other methods.

In FIG. 5, next, a brightness equal to or less than the threshold value which is stored at the time of recipe registration toward inner spacers on the right and left sides (or both sides) from the center between the inner spacers is searched for (504). For example, a second position related to the epitaxial growth layer is specified based on the plurality of first positions. As a specific example, the second position is specified as a center position between two first positions, that is, a center position 603 and a center position 703 between the inner spacers. As another specific example, the second position is specified as a peak position between the inner spacers.

In addition, a plurality of edge positions (third position) related to the epitaxial growth layer are specified by searching for a brightness equal to or less than the threshold value toward right and left inner spacers based on the center position and the threshold value registered in the recipe. For example, the system control unit 110 specifies the plurality of edge positions by searching from the center position 603 and the center position 703 toward both sides of the signal profile, as illustrated in FIGS. 6B and 7B. In this manner, the edge positions can be respectively specified on both sides of the center position.

Next, the system control unit 110 specifies the edge position (505). In a case where there is a brightness equal to or less than the threshold value as illustrated in FIG. 6C, the position of the brightness (as a more specific example, the position of a brightness equal to or less than the threshold value which is first found in each searching direction) is set as an edge position 604 (third position) of the epitaxial portion. On the other hand, in a case where there is no brightness equal to or less than the threshold value as illustrated in FIG. 7C, an end portion of the inner spacer is set as an edge position 704 (third position). The end portion of the inner spacer is specified as, for example, a point at which a brightness is minimized between inner spacers.

Here, in the present example, a brightness “equal to or less than the threshold value” is searched for, but a brightness “less than the threshold value” may be searched for. That is, in a case where all brightness values between two inner spacers are equal to or greater than the threshold value or in a case where all brightness values between two inner spacers exceed the threshold value, the system control unit 110 calculates a distance related to the epitaxial growth layer based on inner spacer positions on both sides instead of the edge position. In this manner, it is possible to calculate the distance by appropriately classifying cases in accordance with a brightness.

As a further modification, instead of determining whether “all” of the brightness values between the two inner spacers are equal to or greater than the threshold value (or exceed the threshold value), it may be determined whether “some” of the brightness values between the two inner spacers are equal to or greater than the threshold value (or exceed the threshold value) .

After the edges on both sides (right and left sides) are detected in this manner, a distance related to the epitaxial growth layer is calculated based on the edge positions (506). For example, a distance between the two edge positions is calculated. As a specific example, a distance 605 is calculated in the example of FIG. 6C, and a distance 705 is calculated in the example of FIG. 7C.

In this manner, the system control unit 110 can calculate a distance and a brightness value related to the epitaxial growth layer from the signal profile in accordance with a predetermined direction which is obtained by irradiating the epitaxial growth layer between the two inner spacers with an electron beam.

In addition, the measured distance is output (507). In a case where there is a brightness equal to or less than the threshold value as illustrated in FIG. 6C, a distance between edges is output as the width of the epitaxial portion. On the other hand, in a case where there is no brightness equal to or less than the threshold value as illustrated in FIG. 7C, a distance between edges is output as a distance between the inner spacers.

Here, the state of the epitaxial growth layer is determined or output based on the distance and the brightness value related to the epitaxial growth layer. For example, the distance between the edges can be output as a numerical value representing the degree of growth of the epitaxial growth layer. Further, in a case where there is no brightness equal to or less than the threshold value (FIGS. 7A to 7C), it is possible to output information indicating that there is no defect in the epitaxial growth layer, and in a case where there is a brightness equal to or less than the threshold value (FIGS. 6A to 6C), it is possible to output information indicating that there is a defect in the epitaxial growth layer.

In this manner, according to the scanning electron microscope and the system control unit 110 in Example 1, it is possible to measure the degree of growth of the epitaxial layer grown in a groove or a hole between inner spacers or determine the presence or absence of a defect from an image of the groove or the hole.

In particular, as illustrated in FIGS. 6A to 7C, the determination is performed based on the inner spacer position 602 (first position), the inner spacer position 702 (first position), the center position 603 (second position), the center position 703 (second position), the edge position 604 (third position), and the edge position 704 (third position), and thus processing based on definite position specification can be performed.

### Example 2

In the present example, an example in which a threshold value is set for each device, and recipe registration is performed will be described. Hereinafter, description of portions in common with those in Example 1 may be omitted.

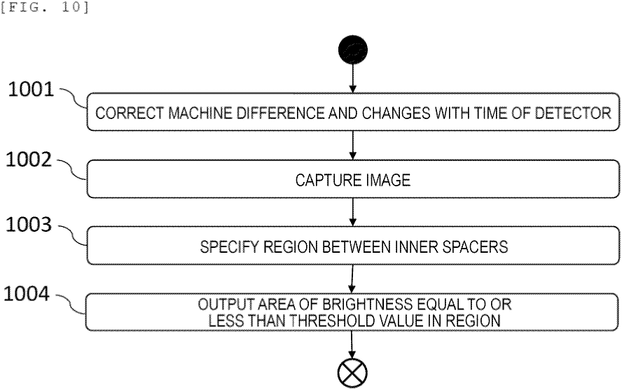

FIG. 8 illustrates an example of a GUI for registering different threshold values for a P-type and an N-type. In a GUI 801, 20% is set as a threshold value for a P-type device. In a GUI 802, 30% is set as a threshold value for an N-type device.

The system control unit 110 stores these two types of threshold values, acquires information indicating whether a device to be measured is a P-type or an N-type, and selects and uses the threshold value according to the information. In this manner, the system control unit 110 stores a plurality of threshold values and selects the threshold value according to the type of layer. Although information indicating the type of layer (for example, information indicating whether the device is a P-type or an N-type) can be input, for example, from a GUI which is not illustrated in the drawing, the system control unit 110 may automatically acquire the information.

Note that, although different threshold values are used for a P-type and an N-type in the present example, the types of devices may be classified according to other criteria.

In this manner, the threshold value is set for each type of device, and thus it is possible to measure the degree of growth or determine the presence or absence of a defect by using appropriate threshold values according to the types of devices.

### Example 3

In the present example, registration and execution of a recipe at the time of performing determination based on an area of a brightness equal to or less than a threshold value will be described. Hereinafter, description of portions in common with those in Example 1 or 2 may be omitted.

FIG. 2 (described above) illustrates a flow of recipe registration, and FIG. 9 illustrates a GUI for determining the threshold value from a histogram. The processing of steps 201 and 202 can be the same as in Example 1. In step 203, a user confirms a maximum brightness (or substantial maximum brightness) of an epitaxial portion from the histogram and inputs a value smaller than the maximum brightness as the threshold value. For example, in a case where the maximum brightness is 10,000, 3,000 is input. In addition, a ratio with respect to the maximum brightness value may be set as the threshold value. In the example of FIG. 9, 3,000 LSB (Least Significant Bit) is input as the threshold value.

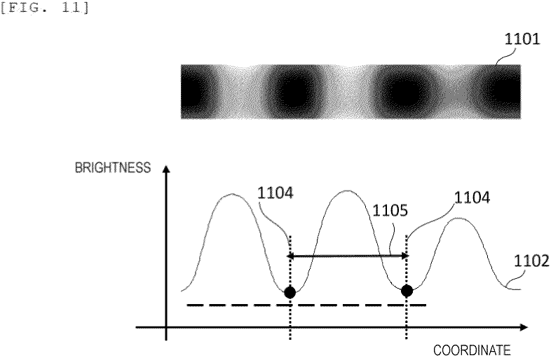

FIG. 10 illustrates a flow of recipe execution according to the present example. Steps 1001 to 1003 can be the same as steps 501 to 503 in FIG. 5.

After step 1003, a brightness equal to or less than the threshold value is detected in a region between inner spacers, and the area of the brightness is output (1004). This area represents the degree of growth of the epitaxial growth layer (however, the larger the value, the lower the degree of growth). In addition, a ratio of the area of the brightness equal to or less than the threshold value to the area of the entire region may be output as the degree of growth. Further, the area of a brightness equal to or greater than the threshold value in the region may be output as the degree of growth (in this case, the larger the value, the higher the degree of growth), or a ratio of the area of a brightness equal to or greater than the threshold value to the area of the entire region may be output as the degree of growth.

Further, a threshold value of an area for which it is determined that epitaxial growth is insufficient (that is, there is a defect) or a threshold value of a ratio may be registered at the time of recipe registration (for example, in a processing in FIG. 2), and the degree of growth or the presence or absence of a defect in the epitaxial growth may be determined and output based on these threshold values.

In this manner, in the present example, the system control unit 110 determines or outputs the state of an epitaxial layer (in the present example, a layer specified by a distance between inner spacers) based on an area having a predetermined brightness range in the epitaxial layer. In this manner, for example, it is possible to perform determination that is resistant to noise.

### Example 4

FIGS. 7A to 7C are an example in which an inner spacer signal is clear, but in a case where there is no inner spacer or a case where the inner spacer signal is not clear 1101, a profile waveform is indicated by 1102. In this case, a distance 1105 between epitaxial growth portions on the right and left sides of an epitaxial growth portion to be measured and a position 1104 at which a signal has a minimum value may be set, or a value determined in advance may be returned. That is, the system control unit 110 may calculate a distance related to an epitaxial growth layer based on a position at which a signal has a minimum value in a signal profile, or may calculate the distance as a predetermined value stored in advance. In this manner, the distance can be output even in a case where there is no inner spacer or a case where an inner spacer is not clear.

### Other Examples

In the above-described examples, a layer of which the state is to be determined is an epitaxial growth layer, and particularly, the state of the layer includes the degree of growth of the layer (for example, represented by a numerical value) and/or the presence or absence of a defect (for example, represented by binary information). In this manner, appropriate determination can be performed specifically for the epitaxial growth layer. However, any of other types of layers may be a target, and in this case, a method of determining and expressing the state of the layer can be appropriately designed by a person skilled in the art.

### REFERENCE SIGNS LIST

101: electron source
102: electron beam
103: deformed illumination diaphragm
104: detector
105: scanning deflection deflector
106: objective lens
107: stage
108: sample
109: controller
110: system control unit (processing system)
111: storage device
112: computation unit
113: input/output unit
114: secondary electron
301: inner spacer (structure)
302: epitaxial portion (layer)
601: threshold value
602: inner spacer position (first position)
603: center position (second position)
604: edge position (third position)
605: distance
701: threshold value
702: inner spacer position (first position)
703: center position (second position)
704: edge position (third position)
705: distance
1101: case where there is no inner spacer or case where inner spacer signal is not clear
1102: profile waveform
1104: position having minimum value
1105: distance

1. A processing system comprising a computer system, wherein
the computer system calculates a distance and a brightness value related to a layer between a plurality of structures from a signal profile in accordance with one direction on a two-dimensional plane related to the layer, which is obtained by irradiating the layer with an electron beam, and determines or outputs a state of the layer based on the distance and the brightness value.

2. The processing system according to claim 1, wherein the structure is an inner spacer.

3. The processing system according to claim 1, wherein the computer system
specifies a plurality of first positions related to regions of the plurality of structures based on the signal profile,
specifies a second position related to the layer based on the plurality of first positions,
specifies a plurality of third positions related to the layer based on a predetermined threshold value and the second position, and
calculates a distance related to the layer based on the plurality of third positions.

4. The processing system according to claim 3, wherein, in a case where the brightness value between the plurality of first positions is equal to or greater than the threshold value, or in a case where the brightness value between the plurality of first positions exceeds the threshold value, the computer system calculates the distance based on the plurality of first positions instead of the plurality of third positions.

5. The processing system according to claim 3, wherein
the second position is a center position between two first positions, and
the computer system specifies the plurality of third positions by searching from the center position toward both sides of the signal profile.

6. The processing system according to claim 1, wherein
the layer is an epitaxial growth layer, and
the state of the layer includes a degree of growth of the layer or the presence or absence of a defect.

7. The processing system according to claim 3, wherein the processing system stores a plurality of the threshold values and selects the threshold value according to a type of the layer.

8. The processing system according to claim 1, wherein the processing system determines or outputs the state of the layer based on an area having a predetermined brightness range in the layer.

9. The processing system according to claim 1, wherein the computer system calculates the distance related to the layer based on a position at which a signal has a minimum value in the signal profile.

10. A charged particle beam apparatus comprising the processing system according to claim 1.
